(19) United States
(12) Patent Application Publication
(10) Pub. No.: US 2007/0181939 A1
(43) Pub. Date: Aug. 9, 2007

(54) Trench-gate semiconductor devices and the manufacture thereof

(75) Inventors: Eddie Huang, Stockport (GB); Raymond J. Grover, Manchester (GB)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: KONINKLIJKE PHILIPS ELECTRONICS, N.V., Eindhoven (NL)

(21) Appl. No.: 10/590,251

(22) PCT Filed: Feb. 17, 2005
(86) PCT No.: PCT/IB05/50595

§ 371 Date: Aug. 17, 2006

(30) Foreign Application Priority Data
Feb. 21, 2004 (GB) 0403934.3

(51) Int. Cl. H01L 29/94

(52) U.S. Cl. 257/330

(57) ABSTRACT

A vertical trench-gate semiconductor device wherein the trench-gates extend in stripes, the source regions extend transversely between the trenchgates in stripes, projection (20) of the source stripes across the trench-gates defines intermediate trench portions (22) between the projected source stripes, and mutually spaced regions (14,14′) of the second conductivity type are to provided immediately below the intermediate trench portions (22) which are connected to source potential. The spaced regions serve to selectively shield portions of the trench-gate from the drain region to suppress their contribution to Cgd and hence Qgd. In particular, they shield those portions of the trenchgate which do not contribute to the channel width of the device, without restricting the current path where a channel is formed.

This invention relates to vertical trench-gate semiconductor devices, and more particularly to such devices which have a striped gate geometry.

Known vertical trench-gate semiconductor devices comprise a semiconductor body and a plurality of trench-gates comprising trenches extending into the semiconductor body with insulated gate electrodes therein. Source and drain regions of a first conductivity type are provided in the semiconductor body and are separated by a channel-accommodating region of a second, opposite conductivity type adjacent the trench-gates.

Two types of trench-gate geometries have been proposed for these known devices. In a “closed-cell” geometry there is a two-dimensionally repetitive pattern in which annular (typically hexagonal) trench-gates surround each transistor cell in the active area. In an “open-cell” geometry there is a one-dimensionally repetitive pattern in which the trench-gates are parallel stripes which each extend across an active area of the device.

Increasingly, the latter, open-cell geometry is being adopted. It can provide an improved trade-off between on-resistance and switching losses relative to a closed cell geometry device. Furthermore, the open-cell geometry needs relatively less critical processing techniques enabling a greater number of transistor cells and therefore a greater channel width per unit area.

As part of the drive towards reducing the cell spacing or pitch in open-cell geometry devices, a striped source region geometry has been proposed in which the source stripes extend transversely with respect to the trench-gate stripes (hereinafter “transverse striped source geometry”). This is in contrast to earlier configurations in which the source regions extended in stripes parallel and adjacent to the trench-gate stripes (hereinafter “parallel striped source geometry”) and requires less critical alignment.

The transverse striped source geometry also has the advantage that the ratio of the areas of the source and channel-accommodating regions at the semiconductor body top surface can be adjusted to alter the performance characteristics of the device without impacting on the alignment of other features.

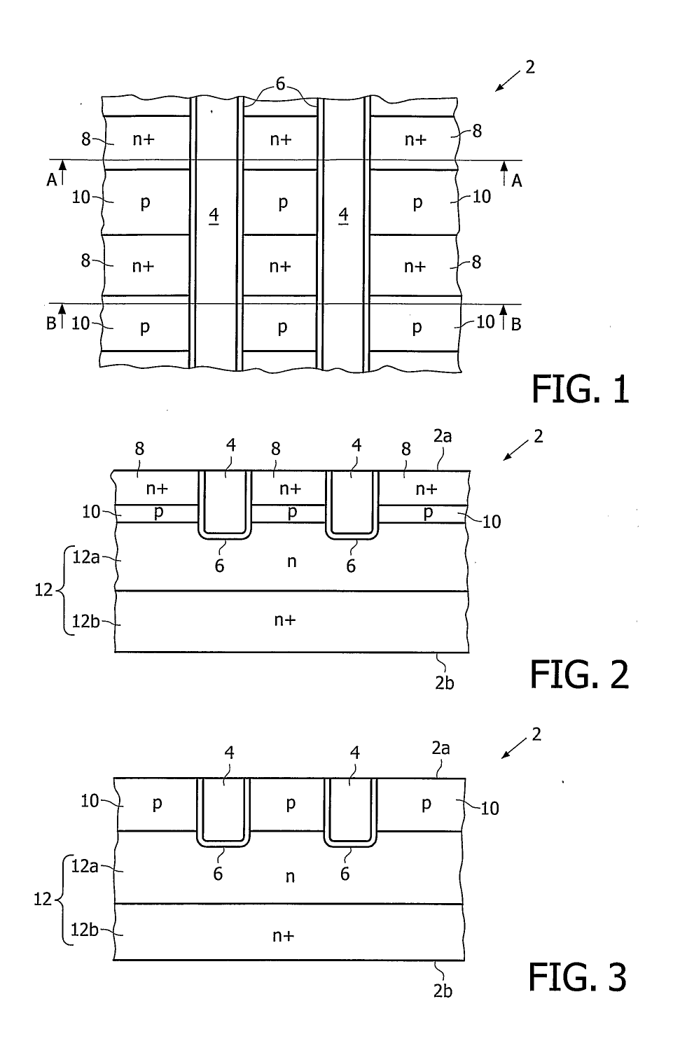

A known device having a transverse striped source geometry is shown in FIGS. 1 to 3 by way of illustration. In the transistor cell areas of this device, source and drain regions 8 and 12, respectively, of a first conductivity type (n-type in this example) are separated by a channel-accommodating region 10 of the opposite second conductivity type (i.e. p-type in this example). Drain region 12 includes a drain drift region 12a formed by an epitaxial layer on a substrate region 12b, the doping level (and therefore conductivity) of the epitaxial layer 12a being low relative to the substrate region 12b.

The gate 4 is present in a trench 6 which extends through the regions 8 and 10 into an underlying portion of the drain region 12. The application of a voltage signal to the gate 4 in the on-state of the device serves in known manner for inducing a conduction channel in the region 10 and for controlling current flow in this conduction channel between the source and drain regions 8 and 12.

The source region 8 and channel-accommodating region 10 are contacted by a source electrode (not shown) at the top major surface 2a of the device semiconductor body 2. The channel-accommodating region extends to the top surface 2a of the semiconductor body between the source stripes for connection to the source electrode to suppress parasitic bipolar action in the device. The substrate region 12b is contacted at the bottom major surface 2b of the semiconductor body by an drain electrode (not shown). The source region extends in transverse stripes between adjacent gate trenches 6.

An example of this transverse striped source geometry is also disclosed in the present applicant's WO-A-03/088364, the contents of which are incorporated herein by reference.

A drawback of the transverse striped source geometry relative to the parallel striped source geometry is that not all of the length of the trench-gates contributes to the channel width of the device. This is because a channel is not formed adjacent portions of the trench-gate between the source stripes. However, these portions of the trench-gate do still contribute to another parameter of the device, the gate-drain capacitance (Cgd) and therefore increases the charge stored by this capacitance during switching (Qgd). Minimisation of Qgd is important in reducing switching losses in the device.

The present invention provides a vertical trench-gate semiconductor device comprising a semiconductor body having a top major surface and a plurality of trench-gates comprising trenches extending into the semiconductor body from the top major surface with insulated gate electrodes therein, the semiconductor body comprising source and drain regions of a first conductivity type which are separated by a channel-accommodating region of a second, opposite conductivity type adjacent the trench-gates, wherein the trench-gates extend in stripes, the source regions extend transversely between the trench-gates in stripes, projection of the source stripes across the trench-gates defines intermediate trench portions between the projected source stripes, and mutually spaced regions of the second conductivity type are provided immediately below the intermediate trench portions which are connected to source potential.

The mutually spaced regions of the second conductivity type (hereinafter “the spaced regions”) serve to selectively shield portions of the trench-gate from the drain region to suppress their contribution to Cgd and hence Qgd. In particular, they shield those portions of the trench-gate which do not contribute to the channel width of the device, without restricting the current path where a channel is formed.

The spaced regions are connected to source potential to provide this shielding effect. Furthermore, this connection also results in a significant part of the depletion charge in the drain region of the device that would otherwise contribute to Qgd flowing to the source electrode. This leads to faster switching of the device, and therefore reduced power losses.

In addition, the spaced regions help to “push out” or broaden the depletion region in the drain region. This effectively widens the depletion region at any given drain-source voltage, therefore giving a lower Cgd at any given drain-source voltage. Again, this acts to reduce further the switching time.

Whilst provision of a continuous second conductivity type region below the trench would give additional shielding of the gate from the drain, this arrangement would impede the current path of the device channel to a greater extent than configurations of the present invention.

Connection of the spaced regions to source potential may readily be achieved by each spaced region being configured to extend from the channel-accommodating region. For example, the spaced region may extend from the lower boundary of the channel-accommodating region, vertically down the side of the trench-gate and then below the respective intermediate trench portion.

In a preferred embodiment, each spaced region extends from the channel-accommodating region on one side of the trench to meet the channel-accommodating region on the other side of the trench.

The depth of each trench may oscillate along its length between depths above and below the lower boundary of the channel-accommodating region, such that the second conductivity type region that provides the channel-accommodating region extends periodically below the trench to form the spaced regions. In this configuration, formation of the spaced regions may not require additional implantation steps, as the implantation which forms the channel-accommodating region can also form the spaced regions.

The invention further provides a method of manufacturing a vertical trench-gate transistor semiconductor device comprising the steps of:

(a) forming a first mask over the top major surface of the semiconductor body defining a striped pattern of windows;

(b) introducing dopant of the first conductivity type for the source region into the semiconductor body via the windows of the first mask;

(c) forming a second mask over the top major surface of the semiconductor body defining a striped pattern of windows which extend transversely to the striped windows of the first mask;

(d) introducing an etchant via the windows of the second mask to form trenches in the semiconductor body, the etchant being selected to etch both the semiconductor body and the first mask material, such that the resulting trenches are deeper than the lower boundary of the channel-accommodating region in the finished device within the lateral extent of the first mask windows and shallower than said lower boundary between the first mask windows.

This method provides a cost efficient way of creating the desired periodic trench depth variation in a single etch process.

In an embodiment of this method, the etchant etches the first mask material more slowly than the semiconductor body to create the desired trench profile.

The invention additionally provides a method of manufacturing a vertical trench-gate transistor semiconductor device comprising the steps of etching grooves of uniform depth into the semiconductor body, and selectively etching portions of the grooves, such that the resulting trenches are deeper than the lower boundary of the channel-accommodating region in the finished device within the lateral extent of the source region stripes and shallower than said lower boundary between the source region stripes.

Furthermore, the invention provides a method of manufacturing a vertical trench-gate transistor semiconductor device having trenches of substantially uniform depth, comprising the steps of forming a mask over the top surface of the semiconductor body; and introducing dopant of the second conductivity type through the windows of the mask for the spaced regions.

Embodiments of the invention will now be described by way of example and with reference to the accompanying schematic drawings, wherein:

FIG. 1 shows a plan view of the semiconductor body of a known trench-gate semiconductor device;

FIGS. 2 and 3 show cross-sectional side views of the semiconductor body of FIG. 1, along lines A-A and B-B, respectively;

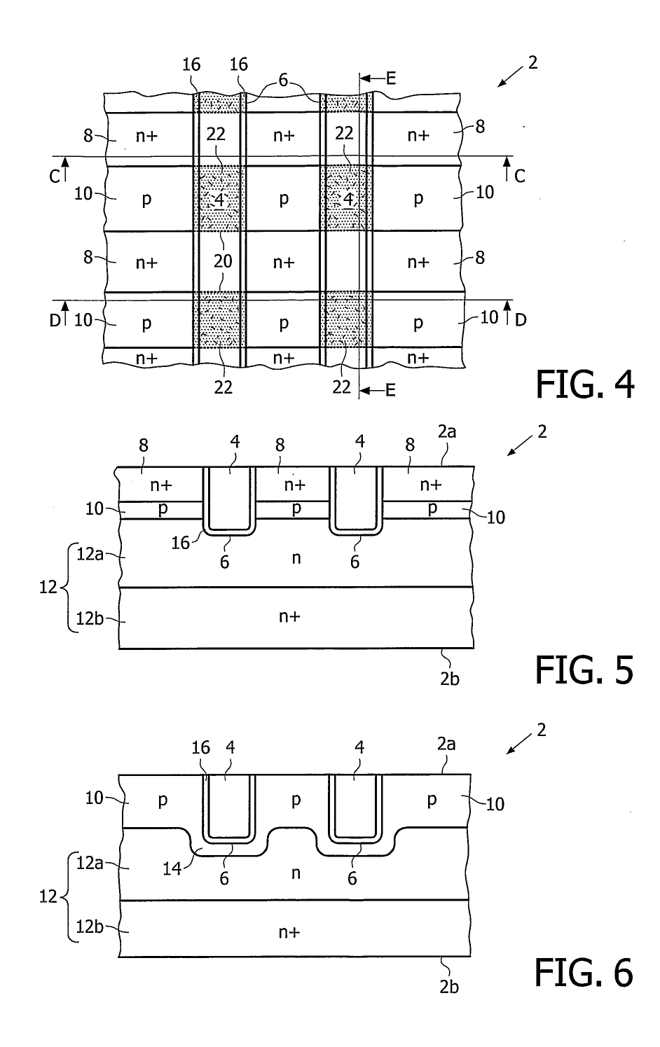

FIG. 4 shows a plan view of the semiconductor body of a trench-gate semiconductor device according to a first embodiment of the invention;

FIGS. 5, 6 and 7 show cross-sectional side views of the semiconductor body of FIG. 4, along lines C-C, D-D and E-E, respectively;

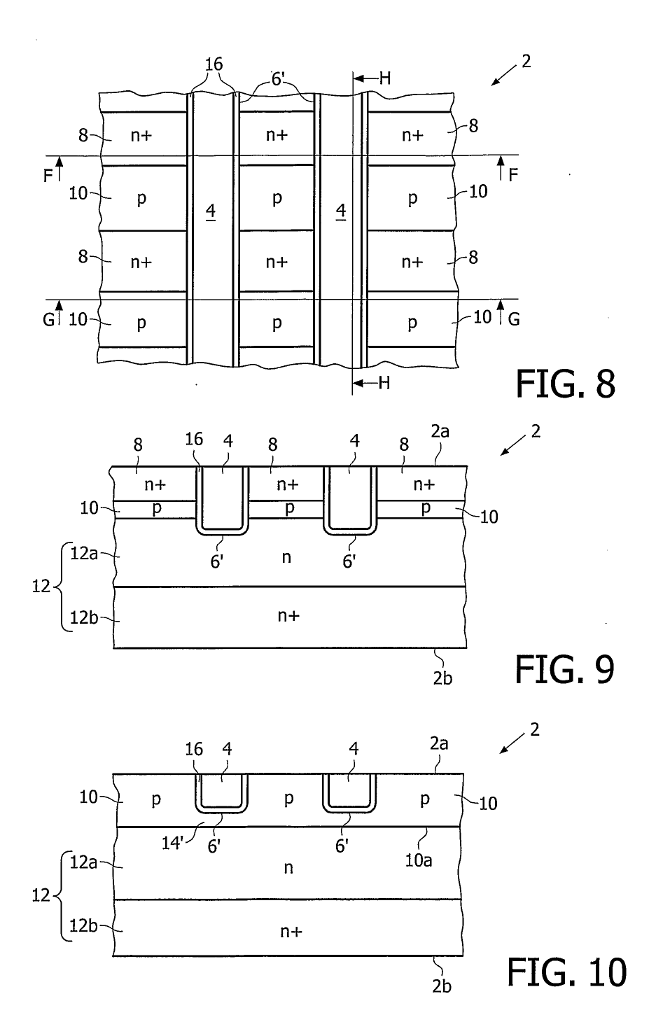

FIG. 8 shows a plan view of the semiconductor body of a trench-gate semiconductor device according to a second embodiment of the invention;

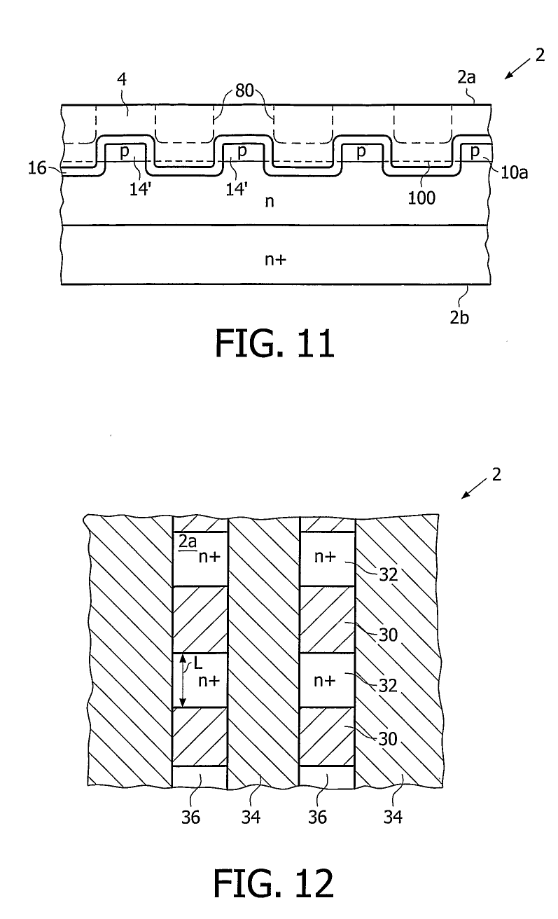

FIGS. 9, 10 and 11 show cross-sectional side views of the semiconductor body of FIG. 8, along lines F-F, G-G and H-H, respectively; and

FIG. 12 shows a plan view of a semiconductor body of a trench-gate semiconductor device according to an embodiment of the invention at an intermediate stage in the manufacture thereof.

It should be noted that the Figures are diagrammatic and not drawn to scale. Relative dimensions and proportions of parts of these Figures have been shown exaggerated or reduced in size, for the sake of clarity and convenience in the drawings. The same reference signs are generally used to refer to corresponding or similar features in modified and different configurations.

In the Figures, only the semiconductor body 2 of each device is shown for clarity. It will be appreciated that finished MOSFET devices will include other features such as source and drain electrodes over the top and bottom major surfaces 2a, 2b, respectively, of the semiconductor body.

In a vertical IGBT embodiment of the invention, the substrate region 12b is of opposite conductivity type (p-type in the examples illustrated) to the drain drift region 12a. In that case, the source region 8 is contacted at the top major surface 2a of the semiconductor body 2 by an electrode called the emitter electrode, and the substrate region 12b is contacted at the bottom major surface 2b of the semiconductor body 2 by an electrode called the anode electrode.

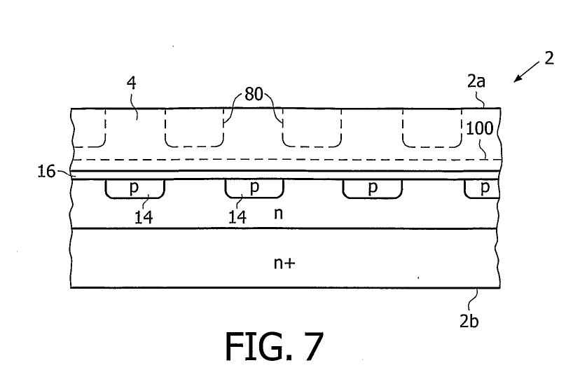

An embodiment of the invention is illustrated in FIGS. 4 to 7. In FIG. 4, dotted lines 20 represent projection of the longitudinal edges of the source stripes 8 across the gate trenches 6. The lines 20 define intermediate portions 22 (shaded in FIG. 4) of the trenches between the source stripes. In FIG. 7, dashed lines 80 indicate the extent of the source stripes 8 into the semiconductor body 2, and dashed line 100 marks the lower boundary 10a of channel-accommodating region 10. They are only shown in outline as the plane of the cross-section of FIG. 7 does not intersect with these features.

As can be seen from the cross-sectional views of FIGS. 5 to 7, regions 14 (p-type in this example) are provided periodically, and are located immediately below the intermediate gate trench portions 22. The regions 14 are mutually spaced apart. The spaced regions 14 are confined in the longitudinal direction with respect to the gate trenches to within the longitudinal extent of the intermediate trench portions 22 so that they do not restrict the current path where a channel is formed below the source stripes 8. It may be preferable for the spaced portions 14 to be narrower than the trench portions 22 to allow for longitudinal spreading of the channel.

As shown in FIG. 6, each spaced region 14 extends downwardly into the drain drift region 12a from the channel-accommodating region 10 adjacent one side of the trench 6, along the sidewall of the trench, adjacent the bottom of the trench and then up the other sidewall of the trench to rejoin the channel-accommodating region on the other side of the trench. Each spaced region 14 may only contact the channel-accommodating region 10 on one side of the trench 6 (to provide a connection to source potential) whilst still providing the desired shielding of the gate 4 from the drift region 12.

It is desirable for the thickness of spaced regions (in the vertical direction, perpendicular to top major surface 2a) below the trench 6 to be minimised and the spaced regions as low doped as possible without causing them to be depleted completely during normal use of the finished device (or at least only depleted completely at the maximum source-drain voltage rating of the device).

Preferably, the thickness of each spaced region 14 below the trench is similar to the thickness (in the same, vertical direction) of the portion of the channel-accommodating region 10 directly below source region 8, with the doping level of each spaced region 14 being similar to that portion of the channel-accommodating region 10. Indeed the parameters of the spaced regions may conveniently be controlled and optimised in the same way as those of the channel-accommodating region.

The spaced regions 14 of FIG. 4 may be formed for example by a suitably masked p-type dopant implantation process after the trenches 6 have been etched.

A further embodiment is illustrated in FIGS. 8 to 11. Spaced regions 14′are formed by modulating the trench depth longitudinally along the trench stripes. The trench bottom oscillates between depths above and below the lower boundary 10a of the channel-accommodating region 10 such that the p-type region that provides the channel-accommodating region 10 also extends periodically beneath the trench 6 to form the spaced regions 14′. The shallower trench portions, and hence the spaced regions 14′, are located laterally between the source stripes, that is below the intermediate trench portions 22 defined above in relation to FIG. 4.

One way of forming the trench configuration shown in FIGS. 8 to 11 will now be described with reference to FIG. 12. A first mask 30 is formed over the top major surface 2a of the semiconductor body 2 which defines a striped pattern of windows 32 having a lateral extent or width (L). An n-type dopant is then implanted via windows 32 for the source regions 8. A second mask 34 is provided over the first mask 30 which is patterned to define striped windows 36 which are orthogonal to the windows 32 of the first mask.

Next, an etch process is carried out. The material of the first mask and the etchant are chosen so that both the first mask and the semiconductor body are etched. Furthermore, the etch rate and thickness of the first mask material are selected such that the etching of the semiconductor material below the first mask is delayed whilst the first mask material is etched away (relative to etching of the initially unmasked surface of the semiconductor body) sufficiently to give the desired trench bottom profile at the end of the etching process. To minimise the mask thickness required, it may be preferable to select a mask material and etchant combination which results in the mask being etched more slowly than the material of the semiconductor body.

In another embodiment, the oscillating trench depth profile may be formed by etching trenches of a uniform depth, and then carrying out a second etch step in which longitudinally, mutually spaced portions of the trench bottom are exposed. The trench is thus etched deeper at these spaced portions to give the desired configuration.

From reading the present disclosure, other variations and modifications will be apparent to persons skilled in the art. Such variations and modifications may involve equivalent and other features which are already known in the art, and which may be used instead of or in addition to features already described herein.

Usually the conductive gate 4 is formed of doped polycrystalline silicon. However, other known gate technologies may be used in particular devices. Thus, for example, additional materials may be used for the gate, such as a thin metal layer that forms a silicide with the polycrystalline silicon material. Alternatively, the whole gate 4 may be of a metal instead of polycrystalline silicon.

FIGS. 4 to 11 illustrate a device having a p-type body region 10 of a uniform depth in each cell, without any deeper, more highly doped (p+) region such as is often used to improve device ruggedness. Some of the cells (not shown) of the device may comprise such a deeper, more highly doped (p+) region. These deeper, more highly doped (p+) regions may be implanted through windows of an appropriate mask.

The particular examples described above are n-channel devices, in which the regions 8 and 12 are of n-type conductivity, the region 10 is of p-type, and an electron inversion channel is induced in the region 10 by the gate 4. By using opposite conductivity type dopants, a p-channel device can be manufactured in accordance with the invention. In this case, the regions 8 and 12 are of p-type conductivity, the region 10 is of n-type, and a hole inversion channel is induced in the region 10 by the gate 4.

A vertical discrete device has been described with reference to FIGS. 4 to 12, having a first main electrode contacting the top major surface 2a and a second main electrode contacting the region 12b at the back surface 2b of the body 2. However, an integrated device is also possible in accordance with the invention. In this case, the region 12b may be a doped buried layer between a device substrate and the epitaxial drain drift region 12a. This buried layer region 12b may be contacted by an electrode at the top major surface 2a, via a doped peripheral contact region which extends from the surface 2a to the depth of the buried layer.

Although Claims have been formulated in this Application to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any Claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The Applicants hereby give notice that new Claims may be formulated to such features and/or combinations of such features during the prosecution of the present Application or of any further Application derived therefrom.

1. A vertical trench-gate semiconductor device comprising
a semiconductor body having a top major surface, and
a plurality of trench-gates comprising trenches extending into the semiconductor body from the top major surface with insulated gate electrodes therein,
the semiconductor body comprising source and drain regions of a first conductivity type which are separated by a channel-accommodating region of a second, opposite conductivity type adjacent the trench-gates, wherein
the trench-gates extend in stripes,
the source regions extend transversely between the trench-gates in stripes, projection of the source stripes across the trench-gates defines intermediate trench portions between the projected source stripes, and mutually spaced regions of the second conductivity type are provided immediately below the intermediate trench portions which are connected to source potential.

2. The vertical trench-gate semiconductor device as recited in claim 1, wherein each spaced region extends from the channel-accommodating region.

3. The vertical trench-gate semiconductor device as recited in claim 2, wherein each spaced region extends from the channel-accommodating region on one side of the trench to meet the channel-accommodating region on the other side of the trench.

4. The vertical trench-gate semiconductor device as recited in claim 1 wherein the depth of each trench oscillates along its length between depths above and below the lower boundary of the channel-accommodating region, such that the second conductivity type region that provides the channel-accommodating region extend periodically below the trench to form the space regions.

5. A method of manufacturing a vertical trench-gate transistor semiconductor device of claim 4 comprising the steps of:
(a) forming a first mask over the top major surface of the semiconductor body (2) defining a striped pattern of windows;
(b) introducing dopant of the first conductivity type for the source region into the semiconductor body via the windows of the first mask;
(c) forming a second mask over the top major surface of the semiconductor body defining a striped pattern of windows which extend transversely to the striped windows of the first mask;
(d) introducing an etchant via the windows of the second mask to form trenches in the semiconductor body, the etchant being selected to etch both the semiconductor body and the first mask material, such that the resulting trenches are deeper than the lower boundary of the channel-accommodating region in the finished device within the lateral extent (L) of the first mask windows and shallower than said lower boundary between the first mask windows.

6. A method of claim 5 wherein the etchant etches the first mask material more slowly than the semiconductor body.

7. A method of manufacturing a vertical trench-gate transistor semiconductor device of claim 4 comprising the steps of:
etching grooves of uniform depth into the semiconductor body, and
selectively etching portions of the grooves, such that the resulting trenches are deeper than the lower boundary of the channel-accommodating region in the finished device within the lateral extent (L) of the source region stripes and shallower than said lower boundary between the source region stripes.

8. A method of manufacturing a vertical trench-gate transistor semiconductor device of of claim 1 having trenches of substantially uniform depth, comprising the steps of:
forming a mask over the top surface of the semiconductor body; and
introducing dopant of the second conductivity type through the windows of the mask for the spaced regions.
